(19) United States
(12) Patent Application Publication
(10) Pub. No.: US 2022/0172431 A1
(43) Pub. Date: Jun. 2, 2022

(54) SIMULATED FACE GENERATION FOR RENDERING 3-D MODELS OF PEOPLE THAT DO NOT EXIST

(71) Applicant: Sony Interactive Entertainment LLC, San Mateo, CA (US)

(72) Inventor: Rebecca Abel, San Mateo, CA (US)

(21) Appl. No.: 17/535,538

(22) Filed: Nov. 24, 2021

Related U.S. Application Data
(60) Provisional application No. 63/119,632, filed on Nov. 30, 2020.

(51) Int. Cl. G06T 17/20; G06N 20/00; G06F 30/23; G06T 15/50; G06F 30/27

(52) U.S. Cl. CPC G06T 17/20; G06N 20/00; G06F 30/27; G06T 15/503; G06F 30/23

(57) ABSTRACT

A method is provided for generating a 3-D model of a face. On example method includes accessing a database of images of faces and processing the images through a machine learning process to identify and label features of each of the faces to train a facial rendering model. The method includes accessing the facial rendering model to request data for rendering a plurality of simulated faces. The request includes, attributes for facial features and attribute variations between the plurality of simulated faces. The method includes processing one or more of the plurality of simulated faces. The processing is configured to generate a three-dimensional (3-D) model based for each respective simulated face. Each 3-D model includes wire mesh data and texture data usable by a content creation application. The facial rendering model enables the plurality simulated faces to be rendered based on a blending of facial parts from the images of faces.

### CLAIM OF PRIORITY

This application claims priority to and the benefit of U.S. Provisional Application No. 63/119,632 filed on Nov. 30, 2020, entitled “SIMULATED FACE GENERATION FOR RENDERING 3-D MODELS OF PEOPLE THAT DO NOT EXIST,” the disclosure of which is incorporated herein by reference in its entirety for all purposes.

### BACKGROUND

### 1. Field of the Disclosure

The present disclosure relates to methods and systems for dynamically generating custom three-dimensional models of generated faces for characters to be animated in video games.

### 2. Description of the Related Art

The video game industry has seen many changes over the years. As computing power has expanded, developers of video games have likewise created content creation tools and games that takes advantage of these increases in computing power. To this end, video game developers have been coding games that incorporate sophisticated operations and mathematics to produce very detailed and engaging gaming experiences.

Example gaming platforms include the Sony Playstation®, Sony Playstation2® (PS2), Sony Playstation3® (PS3), Sony Playstation4® (PS4), and Sony Playstation5® (PS5), each of which is sold in the form of a game console. As is well known, the game console is designed to connect to a display (typically a television) and enable user interaction through handheld controllers. The game console is designed with specialized processing hardware, including a CPU, a graphics synthesizer for processing intensive graphics operations, a vector unit for performing geometry transformations, and other hardware, firmware, and software. The game console may be further designed with an optical disc reader for receiving game discs for local play through the game console. Online gaming is also possible, where a user can interactively play against or with other users over the Internet. As game complexity continues to intrigue players, game and hardware manufacturers have continued to innovate to enable additional interactivity and computer programs.

Although gaming continues to see tremendous improvements in graphics, speed, and realism, the generation of faces for characters is still a very tedious process. Depending on the context of the game, design engineers are required to spend substantial amount of time creating custom faces to be utilized in games. In some cases, many faces are needed in order to fill the needs for non-player characters. The time spent to generate a video game is significantly increased, given the need to create many variations of faces for different roles. The process associated with generation of faces is tedious, and can require significant engineering skill and artistic skills. Unfortunately, while the tedious process of generating faces for use in characters in video games has seen some quality improvements and minor changes in workflow, it continues to require significant time demands in order to create the realism demanded in current gaming environments.

It is in this context that implementations of the disclosure arise.

### SUMMARY

Implementations of the present disclosure include devices, methods and systems relating to dynamically generating custom three-dimensional models of faces for characters to be animated in video games. Generation of 3-D models of faces from computer generated images of faces reduces the time needed to generate faces using traditional computer animation programs. Further, when simulated faces are needed for non-player characters, faces may be generated automatically using defined inputs for variation control. If simulated faces are used for main characters, additional adjustments may be made to the mesh, textures, settings and associated blendshapes used for animating the faces. As the simulated faces result in faces of people that do not exist, more free use and variations can be made of these simulated faces for faster generation and implementation into games and graphics related programs.

In one embodiment, a method for generating a three-dimensional model of a face is provided. The method includes accessing a database of images of faces and processing the images through a machine learning process to identify and label features of each of the faces. The labels provide a descriptive characteristic of the faces. The machine learning process produces a facial rendering model. The method further includes generating a simulated face based on a request that includes attributes for facial features to be included in the simulated face. The method includes generating a three-dimensional (3-D) model based on the simulated face. The 3-D model is defined in a file that includes wire mesh data for the simulated face and texture data for the simulated face. The method includes accessing the file via a content creation application. The file enables use of the 3-D model on a rig of a character to be animated for a video game.

In some implementations, the attributes for the facial features of the simulated face are associated with inputs provided by the content creation application for setting an amount of attribute variation of one or more of the attributes.

In some implementations, the method further includes providing a control via the content creation application to set a number of simulated faces to generate based on request.

In some implementations, control via the content creation application further provides an input for setting a variation among simulated faces. The input qualifies a degree of similarity between the simulated faces generated when the number of simulated faces is two or more simulated faces.

In some implementations, the facial rendering model is generated during a face image training process. The face image training process includes processing facial feature extractors that identify facial features in each of the faces and facial feature classifiers that provide for labeling of the features. In some cases, the process can include feature mapping and automatic feature detection.

In some implementations, generating the simulated face includes accessing the facial rendering model using the attributes for facial features to be included in the simulated face. The facial rendering model is configured to output data that includes parts of the images from the faces of the database assembled to generate said simulated face. The output data includes blending data used to assemble said parts of images when generating the simulated face. The blending data generated by said machine learning process adjusts said texture data and lighting impacts on lighting to produce said simulated face, as a realistic face of a person that does not exist.

In some implementations, the requested attributes for facial features to be included in the simulated face include a gender, and a plurality of sub-attributes desired for the simulated face, and one or more of the sub-attributes is associated with an attribute variation set via the content creation application.

In some implementations, the simulated face is one of a plurality of simulated faces requested to be generated and the method includes applying a variation amount simulated faces setting that defines how similar or dissimilar each one of the simulated faces is with respect to each other.

In another embodiment, a method is provided for generating a 3-D model of a face. The method includes accessing a database of images of faces and processing the images through a machine learning process to identify and label features of each of the faces to train a facial rendering model. The method includes accessing the facial rendering model to request data for rendering a plurality of simulated faces. The request includes, attributes for facial features and attribute variations between the plurality of simulated faces. The method includes processing one or more of the plurality of simulated faces. The processing is configured to generate a three-dimensional (3-D) model based for each respective simulated face. Each 3-D model includes wire mesh data and texture data usable by a content creation application. The facial rendering model enables the plurality simulated faces to be rendered based on a blending of facial parts from the images of faces.

In some implementations, the request includes input data associated with attribute variation for selected attributes; the attribute variation sets a percentage amount of variation away from an input attribute.

In some implementations, the facial rendering model is generated during a face image training process. The face image training process includes processing facial feature extractors that identify facial features in each of the faces and facial feature classifiers that provide for labeling of the features.

In some implementations, generating the simulated faces includes accessing the facial rendering model using the attributes for facial features to be included in the simulated face. The facial rendering model is configured to output data that includes parts of the images from the faces of the database assembled to generate said simulated faces. The output data includes said blending of facial parts from the images of faces when generating the simulated faces. The blending is at least in part controlled by said machine learning process to adjust said texture data to produce realistic simulated faces of people that do not exist.

In some implementations, the attributes for facial features to be included in the simulated face include a gender, and a plurality of sub-attributes desired for the simulated face, and one or more of the sub-attributes is associated with an attribute variation set via the content creation application.

In some implementations, the each of the simulated faces represents a face of a person that does not exist.

In some implementations, the method further includes identifying a set of blendshapes for each one of the simulated faces. The blendshapes being identified automatically based on attributes present in the simulated faces.

In some implementations, the content creation application uses a plug-in to provide functionality for accessing the facial rendering model to generate said simulated faces and producing said 3-D models.

In some implementations, the content creation application enables application of the 3-D models of the simulated faces to be applied to one or more rigs of characters.

In some implementations, one or more rigs of characters are designed for animation using predefined blendshapes. The predefined blends shapes are automatically selected for each of the 3-D models of simulated faces.

In some implementations, the rigs of characters are usable in one or more video games.

Various embodiments will be described below for purposes of providing examples of the disclosed methods and systems. Other aspects and advantages of the disclosure will become apparent from the following detailed description, taken in conjunction with the accompanying drawings, illustrating by way of example the principles of the disclosure.

### BRIEF DESCRIPTION OF THE DRAWINGS

The disclosure may be better understood by reference to the following description taken in conjunction with the accompanying drawings in which:

FIG. 1A illustrates a flowchart of a method that can be utilized to generate a simulated face for use in producing a 3-D model implemented and used in a content creation application.

FIG. 1B illustrates an example method for training the facial rendering model, and utilizing the facial rendering model for generating simulated faces, in accordance with one embodiment.

FIG. 2A illustrates a process diagram where a content creation application is utilized to make selections for the type of simulated face requested, in accordance with one embodiment.

FIG. 2B illustrates an example of the content creation application 202 having controls for defining attribute variations, in accordance with one embodiment.

FIG. 2C illustrates an example of another feature accessed via the content creation application, in accordance with one embodiment.

FIG. 2D illustrates another example of features accessed via the content creation application 202, in accordance with one embodiment.

FIG. 3 provides a flowchart diagram that identifies method operations performed when generating a simulated face for use in producing a 3-D model, in accordance with one embodiment.

FIG. 4 illustrates another method for generating multiple 3-D models, for use in digital casting of faces, in accordance with one embodiment.

FIG. 5 illustrates another embodiment, where a plurality of 3-D models is generated from a plurality of simulated faces, in accordance with one embodiment.

FIG. 6 is a block diagram of a Game System, according to various implementations of the disclosure.

### DETAILED DESCRIPTION

The following implementations of the present disclosure provide devices, methods, and systems relating to the dynamically generating custom three-dimensional models of faces for characters to be animated in video games. It will be obvious, however, to one skilled in the art that the present disclosure may be practiced without some or all of the specific details presently described. In other instances, well known process operations have not been described in detail in order not to unnecessarily obscure the present disclosure.

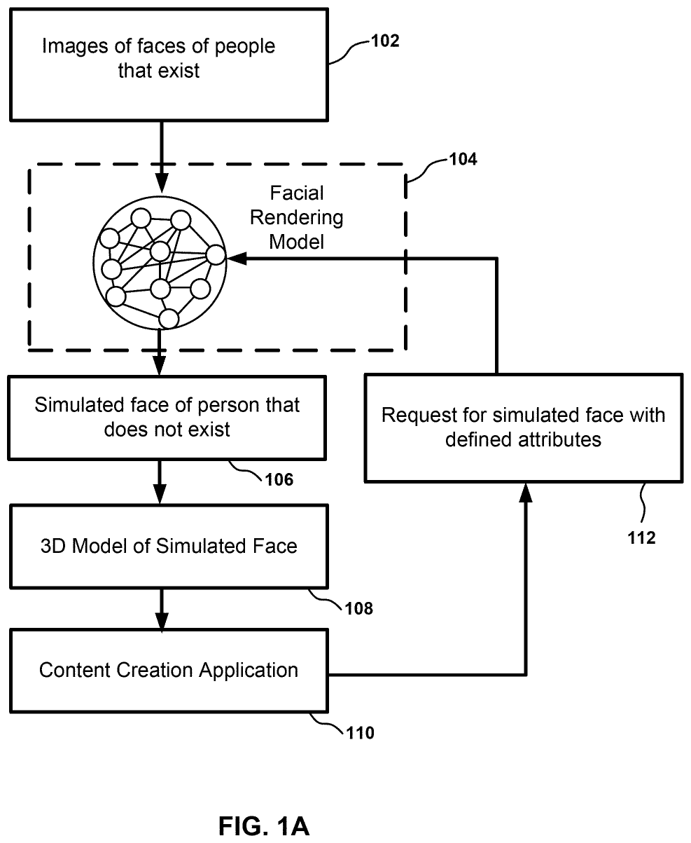

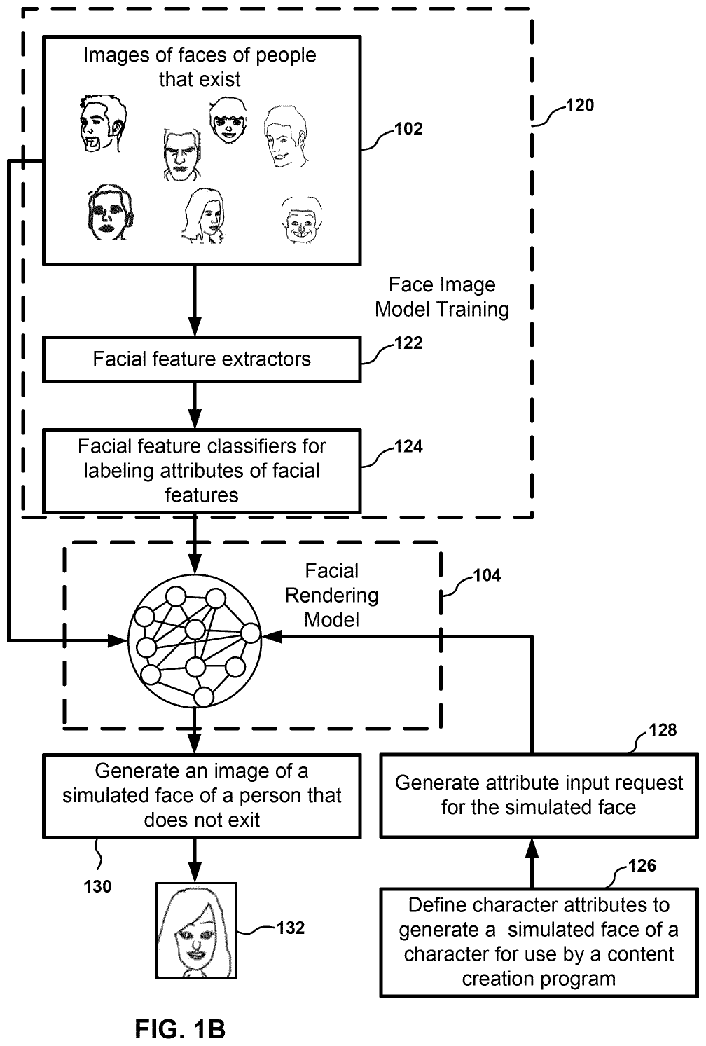

FIG. 1A illustrates a flowchart of a method that can be utilized to generate a simulated face for use in producing a 3-D model implemented and used in a content creation application. In one embodiment, images of faces of people that exist are accessed in operation 102. These images of faces can be accessed from a database, or from a source of people that provide permission to use their faces. In one embodiment, the images of faces are defined as files, e.g. pictures of the person's face and head. In some embodiments, the pictures include more than the face of the person, and processing to identify the face in the picture can be performed. In operation 104, the facial rendering model is utilized to service requests for simulated faces. In one embodiment, a request for simulated face with defined attributes can be provided in operation 112.

The request is communicated to the facial rendering model 104, which can access the images of faces 102, in order to generate the simulated face of a person that does not exist in operation 106. As will be discussed in more detail below, the facial rendering model 104 is a trained model that can identify features on faces, and understand the attributes associated with those features. Based on that request, which included defined attributes in operation 112, the simulated face of a person that does not exist in operation 106 is generated. The simulated face, in one embodiment, has been digitally blended so that attributes utilize from different faces in the images of 102, will appear realistic and smoothly constructed.

In operation 108, a three-dimensional (3-D) model of the simulated face is generated. The 3-D model is a facial reconstruction in 3 dimensions using information from the simulated face. The 3-D model, in one embodiment, is a digital file that can be utilized as input to a content creation application 110, which can then utilize a 3-D model to make further adjustments to the 3-D model, refinements, and integration with one or more rigs of characters being developed for a video game. In accordance with one embodiment, the generated 3-D model is based on a simulated face, which is of a person that does not exist. In this manner, it is possible to make computer-generated variations to the simulated models that are produced, in order to identify different types of facial characteristics desired for a specific video game character.

FIG. 1B illustrates an example method for training the facial rendering model 104, and utilizing the facial rendering model for generating simulated faces, in accordance with one embodiment. As shown, a face image model training operation 120 utilizes as input the images of faces of people that do exist 102. In one embodiment, the training process utilizes one or more facial feature extractors 122. The facial feature extractors are configured and programmed to identify faces in image files. Once the faces have been identified, the facial feature extractor is programmed to identify a plurality of features in the identified faces. The features identified by the facial feature extractors 122 can include, for example, gender, approximate age, face shape, hair type, hair length, skin tone, complexion, eyebrows, eyes, mouth, teeth, ears, nose, lips, brow, eye size, and variations in shapes of the various facial features. In one embodiment, the facial feature extractors 122 are trained extractors that have been programmed to identify specific shapes, objects, images, that may be present in one or more images being examined. In one embodiment, the facial feature extractors 122 can improve over time based on learning algorithms utilize for refining the extractor parameters.

In operation 124, facial feature classifiers are configured to receive features from the facial feature extractors 122, and provide labeling attributes for the facial features. By way of example, the classifiers are configured to assign labels that descriptively identify the type of feature found in the images. The labels can identify characteristics of the attributes, such as labeling eyes as the color blue, the hair as the color brown, the lips being narrow, the brow being thick, the skin tone being fair or tan, the face shape being elongated, pear-shaped, wide, narrow, etc. These classifiers then provide the classified and labeled features to the facial feature rendering model 104 for further processing.

In one embodiment, the facial feature rendering model 104 is configured to process the labels and assign nodes to the labels, as well as make computations that adjust the strength in values between nodes based on the identified and labeled features provided by the classifiers. In one embodiment, the facial rendering model 104 implements machine learning in order to generate a simulated face based on a request and attributes associated with the request. In one embodiment, the machine learning utilizes a process referred to as a style generative adversarial network (StyleGAN). In GAN, the term “generative” is used because it makes something, i.e., a simulated face image. The term “adversarial” is used, since the process battles against each other in some kind of game, and the term “network” refers to neural networks.

In GAN, two neural networks compete against each other to make the simulated face image. The machine learning model of a StyleGAN, in one embodiment, is provided with a request that identifies the attributes desired for the simulated face. In one operation, one neural network of the machine learning model is configured to generating content, and a second neural network is looking for flaws in the content generated by the first neural network. By identifying flaws, this allows the first neural network to correct its output until there are no identifiable flaws in a particular reference field. In one embodiment, the facial rendering model 104 is configured to operate on the input face images 102, and process the different features identified.

In some embodiments, the features are process based on styles, e.g. course styles that encompass global aspects of a face, e.g. the hair, the face shape, the pose. In other style could be a middle style, where more detailed features are analyzed such as the eyes, eyebrows, the nose, etc. In another process, a finer style can be utilized to examine the color schemes in the pictures themselves. Using this process, it is possible to better blend images of features, e.g., when different facial feature parts from different images of people are combined. Further, by correcting the flaws, the blending becomes more efficient to provide smooth transitions in the facial features of the resulting simulated face, and in accordance with the requested attributes and defined variations.

As shown in FIG. 1B, a user of the content creation program can provide inputs for defining character attributes to generate a simulated face for a character in operation 126. Based on the defined character attributes requested using the content creation program 126, operation 128 will generate attribute inputs provided as the request for the simulated face. By way of example, an artist or game programmer may be attempting to design a new face for a character of a video game. The character may be a hero or main character in the game, or can be a non-player character (NPC). Typically, NPC's do not require high levels of detail in their artistic rendering of the face, since those NPC characters are usually not the center focus of a game player. Additionally, NPC characters may be moving around in ways that make their face less visible or focused on during gameplay. In one embodiment, the defined character attributes for the simulated face, may define the level of detail requested in the simulated face.

If the designer is generating faces for NPC characters, the level of detail provided in the resulting face may be reduced. The level of detail can be of lower resolution, e.g., relative to high-resolution images of faces of main characters or heroes in the game. In one embodiment, the input request in operation 128 will define the level of detail desired for the simulated face, and the facial rendering model 104 can produce an image of the simulated face of a person that does not exist in operation 130. The simulated image 132 is shown as an example, of a simulated face that is of a person that does not exist. In contrast, the images of faces of people that exist are shown in 102.

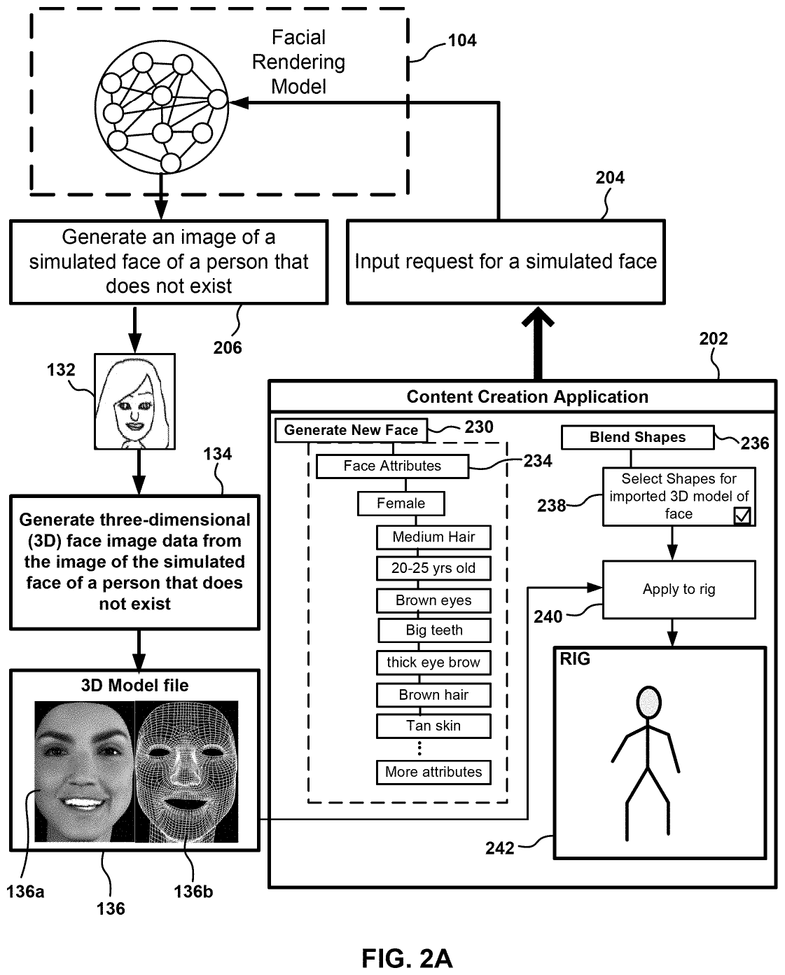

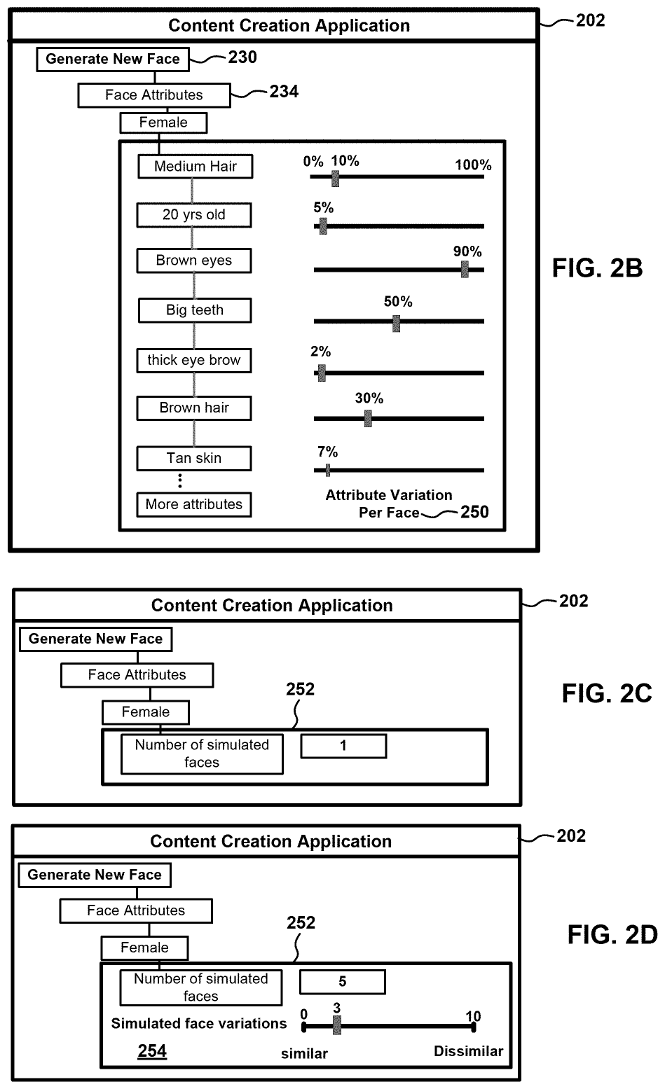

FIG. 2A illustrates a process diagram where a content creation application 202 is utilized to make selections for the type of simulated face requested, in accordance with one embodiment. As shown, the content creation application 202 can include a feature to allow the generation of a new face 230. This feature allows the user to select face attributes 234 that are desired for the simulated face to be generated. As mentioned above, the facial rendering model 104 has access to facial features from images of faces of people that exist, and learning parameters associated with the labels that were created based on the input features utilized for the face image model training 120. As shown, the content application 202 allows the user to select any number of attributes.

By way of example, the attributes can include a gender, such as female. Additional sub attributes can include for example, medium hair, 20 to 25-year-old, brown eyes, big teeth, thick eyebrow, brown hair, tan skin, and any number of additional attributes that can be descriptive of a face or person or head of the person. In the content creation application 202, the generated new face 230 feature can be provided by the content creation application 202 itself, or by way of a plug-in. In one embodiment, the content creation application 202 may be the commercially available application for creating and engineering images of characters to be animated in one or more other applications.

One commercially available application is known as MAYA™ which is a 3-D computer animation, modeling, simulation, and rendering program. MAYA™ is an Autodesk™ product. In one embodiment, the content creation application 202 can be modified to include other automation features, such as processing of blendshapes 236. Basic use of blendshapes is a feature that is provided by MAYA™. However, in accordance with one embodiment, the blendshapes 236 described herein are unique features that can be added to an existing content creation application 202 to enable selection of shapes for imported 3-D models of faces 238. By way of example, the selection of blendshapes can be performed using a matching algorithm that predefined specific types of blendshapes that would be useful for a specific 3-D model of faces being imported into the content creation application. It should be understood that any number of commercially available applications may be utilized, which can implement the simulated face generation methods described herein. The implementation of the methods described herein can be in the form of specific features that are part of an application, or can be provided by plug-ins that work with existing applications, or can be provided by a software as a service (SAAS) application.

In one embodiment, the selection of the blendshapes that would be useful for the specific 3-D model of the face can be algorithmically selected, based on blendshapes that would fit the specific type of face. In some implementations, a process could find, for example, blendshapes that work for a young girl or an overweight elderly woman instead of areas of the face since most people move all parts of their face. Thus what they need to move would be predicated on a set of example animation. In one embodiment, the selection of blendshapes is performed based on examination of the 3-D model file for specific parts of the face. For instance, examination of the face can programmatically be divided into specific facial features, which are examined one after another. Based on this examination, a collection of selection inputs can be identified that will be used for selecting the specific blendshapes that would be optimally used for the specific 3-D model file being imported. In one embodiment, a deformation transfer can be applied, which includes a process of transferring the blendshapes needed for animation from one head to a different head. In another embodiment, it is possible to fabricate new not previously existing blendshapes based on example animation or 4d data. The above-described functionality is different than standard blendshapes processing, which requires the artist to select or make animation specific blendshapes to a target face.

This process is time-consuming which requires an artist select features on the wire mesh of the 3-D model file, move different vertices in different directions, and make judgment calls of when specific facial expressions are being made are proper for the face. By automating this process, it is possible to automatically apply a specific set of blendshapes for specific input 3-D model files. This will filter out blendshapes that are not appropriate for the 3-D model file, and reduce the amount of time needed by a programmer to create the blendshapes for each and every imported 3-D model file. In some embodiments, the programmatically selected blendshapes can also be adjusted by the programmer using standard adjustment techniques, e.g. moving vertices on the mash until the desired correction has been made. However, by programmatically selecting blend shapes for 3-D models, significance amount of time are saved by the programmer. This feature is also beneficially useful for creating NPC characters, since NPC characters require less fidelity and can be made with lower resolution as compared to hero or main character graphics.

Once the input request for the simulated face 204 has been provided to the facial rendering model 104, an image of a simulated face of the person that does not exist is generated in operation 206. Image 132 shows a face of a female, meeting the attributes selected by the designer, and output by the processing of the facial rendering model 104. Once the simulated face image 132 has been generated, a three-dimensional face image is generated 134 based on the simulated face of the person that does not exist. In one embodiment, the 3-D face image represents the data that will be part of the 3-D model file 136.

In one embodiment, the 3-D model file 136 is in the format of an OBJ file, or an FBX file. It should be understood that other type of file formats can be utilized, depending on the target content creation application 202. In one embodiment, the 3-D model file 136 will include texture data 136a for the resulting 3-D model of the face. In one embodiment, the 3-D model file 136 will also include mesh data 136b, representing the contours of the 3-D face generated by the 3-D model generation process. As will be appreciated by those skilled in the art, a file generated with this information can then be imported and utilized by the content creation application in order to make finer detail changes, creative adjustments, and/or corrections. In some embodiments, once the 3-D model file 136 has been generated, it can be imported and applied to a rig 240. A rig is typically referred to as the computer model of a person that is to be animated. Sometimes, a model implies it's just the mesh. However, a rig is generally mesh, textures, shaders, joints, blendshapes and/or controls.

An animator typically refers to a rig in the context of a rigging process. Rigging is what makes deforming a character possible. In one embodiment, this includes the process of taking a static mesh, creating an internal digital skeleton, creating a relationship between the mesh and the skeleton (known as skinning, enveloping or binding) and adding a set of controls that the animator can use to push and pull the character and/or features of the character. One aspect of rigging includes the generation of the face and head, and making modifications including those associated with blend shapes.

As mentioned above, blendshapes allow an animator to move the facial features and different orientations to create different expressions. In some embodiments, multiple blendshapes are created and are utilize at different times to create animated effects of the face, e.g. during animated movement. Accordingly, the 3-D model file 136 can then be applied to the rig 240, where the animator can continue to make any adjustments to the face as necessary for finishing the characteristics of the face and head of the character. Once complete, the character can be animated by one or more other programs, and then ported into video games for animated use, and control by a game engine, during gaming.

FIG. 2B illustrates an example of the content creation application 202 having controls for defining attribute variations, in accordance with one embodiment. As shown, the various attributes defined for a female face can each be associated with an input control. The input control can provide a setting, such as an amount of attribute variation to be allowed for the specific attributes associated with the simulated face being generated. The example illustrates that for the attributes “medium hair” a 10% variation is allowed. This means that the setting for medium hair can vary up to +/−10%. For the age attribute, the setting is shown to be +1-5%. Since the attribute ages 20, +/−5% would be a range that extends between 19 and 21. Similar variations can be applied individually to different attributes of the simulated face being requested. This feature provides for more control over the variance that can be generated by the facial rendering model 104. In one embodiment, the attribute variations per face 250, can be associated with the template. For example, any number of templates can be provided to allow for commonly used attribute variations for specific types of faces. In such an example, it is possible to start with a template and then make further input adjustments to the attribute variations, which are then utilized as part of the input request for simulated face 204, that is provided to the facial rendering model 104.

FIG. 2C illustrates an example of another feature accessed via the content creation application 202, in accordance with one embodiment. Interface 252 provides a way for the selection of the number of simulated faces being requested, for the example female face to be generated. In this example, the selection has been made for one simulated face. Using this input setting, the input request can be made for the simulated face, and baseline attribute variations from a standard template can be used. The baseline attribute variations can be selected automatically, based on typical variations for different attributes, based on the type of face. As noted above, if the user desires to have more flying granular adjustment to the variations, setting such as those shown in FIG. 2B may be accessed and made as part of the request.

FIG. 2D illustrates another example of features accessed via the content creation application 202, in accordance with one embodiment. In this example, interface 252 receives input for the selection of five simulated faces. In this example, the artist may be looking for a specific type of face, and wishes to generate five faces. In one embodiment, selecting multiple phases using similar attribute variations will allow for a type of digital casting. A digital casting provides an interface that shows all of the faces that were generated, and enabling the engineer to select one or more of the faces for use in further animation. In one embodiment, when multiple faces are being simulated, a feature provided enables setting 254 of a similarity between the faces. As illustrated, the input was provided as three, meaning that the five faces will be substantially similar, and each phase will have a similar attribute variation. If the dial is move closer to ten, the face variations of the simulated faces will be much different between them.

For example, it is possible to randomly or dynamically set the attribute variations per face to be different for each of the five simulated faces. In some embodiments, the attribute variation per face 250 can be set based on a template for each one of the simulated faces, with variations between them. The greater the variations, the more dissimilar the number simulated faces will be (i.e. consistent with the similarity setting). As mentioned above, the settings can be provided using dynamic interfaces that are integrated with the content creation application 202, as either native controls of the application or as plug-in controls. The resulting input data provided in the request made to the facial rendering model 104 will be to control the variation of the simulated images that are generated, and then subsequently rendered into 3-D model files. It should be understood that the examples of using a female for a face in FIGS. 2B-2C is only by way of example. It is possible to request a face of a male, an animal, a monster, a character type, or any other type of digital image or object the can be simulated for use in 3-D model file generation.

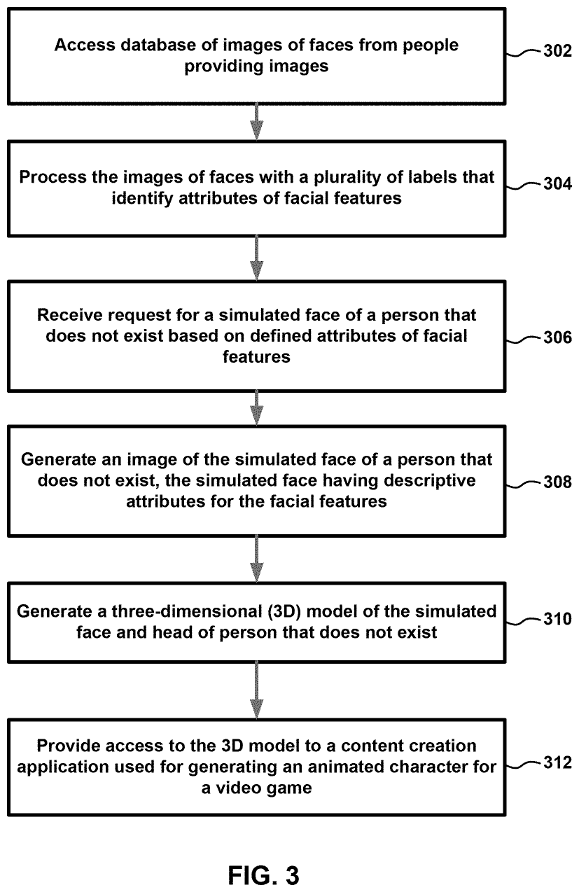

FIG. 3 provides a flowchart diagram that identifies method operations performed when generating a simulated face for use in producing a 3-D model, in accordance with one embodiment. In operation 302, the method includes accessing the database of images of faces from people that provide images. These images may be of real people, and the images may be provided with consent or by copyright license. The database may contain various types of image files, such as images of females of varying ages, hairstyles, skin tone, facial shapes, and associated variations of the various attributes. The same can be said for images of males of varying ages, hairstyles, skin tone, facial shapes, and associated variations of the variation attributes.

As mentioned above, it is also possible to import into the database images of non-people characters, such as monsters, animals, objects, characters, etc. In one embodiment, the database of images of faces will have a sufficient number of images to draw upon in order to provide a robust training set of data. In some embodiments, the images in the database may include 10 or more, 100 or more, 1000 or more, thousands, or even hundreds of thousands of images. The greater the image library, the more variations can be identified in the images themselves and will provide for a more robust training set.

In operation 304, the image faces from the database are processed in order to generate a plurality of labels that identify attributes for the facial features in each face image, in accordance with one embodiment. In this embodiment, image recognition software is utilized to identify a face in an image. Using image and object recognition, the pixel data is analyzed in order to identify features associated with the face. These features include, without limitation, the shape of the face, the length of the hair, the skin tone, the nose, the ears, the eyes, the color of the eyes, the eyebrows, the cheekbone structure, the chin structure, facial hair, the condition of the skin, and other identifiable features. As these features are identified, labels are associated to those features that are extracted from the images. As mentioned above, a feature extractor can be utilized in conjunction with the machine learning process in order to identify features and images and associate labels to the features that the fine the attributes of the face being analyzed.

Once the features have been labeled to identify the attributes of the facial features, the information is processed by the machine learning model to define the facial rendering model 104. This processing can be continuously reinforced during multiple training sessions in order to generate the face image model training 120 operations. The training process can be performed before the need arises to request a simulated image of the face. In some embodiments, the training process is a continuous process that learns and grows over time, as new faces are generated. For example, the generated simulated faces can also be part of the training data, and can be added to the database of images. In this manner, the facial rendering model 104 can continue to expand and refine its decisions for identifying facial features when requests are made for generating a simulated face.

In operation 306, a request for simulated face of a person that does not exist is received, in accordance with one embodiment. The request will identify attributes for the facial features requested, and the inputs for defining the attributes can be by way of a content creation application 202, a mini application that interfaces with the content application 202, or a plug-in that works with the content application 202. As mentioned above, the request can be provided with additional information set by the designer, such as attribute variations. The attribute variations can identify how variant each attribute can be around a specific input attribute. In some embodiments, the attribute variations can be provided using a template, and in other ways the attribute variation can be customized for a specific project, target face, or context of gaming application.

In operation 308, an image of the simulated face that was generated in operation 306, is generated. The simulated face is of a person that does not exist, since portions of the faces in the database of images have been utilized and blended to generate the simulated face. The simulated face will have descriptive attributes that comply with the facial features requested in the request. In some embodiments, the facial features may vary, depending on the selections made by the facial rendering model 104. In some embodiments, the selections made by the facial rendering model 104 can be fine-tuned to avoid the partners from the target attributes. In some embodiments, the settings can be adjusted so that more variation is made around the input attributes. In still other embodiments, the attributes are attempted to define a very specific simulated face, and the facial rendering model 104 with generates a simulated face that best fits the selected and requested attributes.

In operation 310, a three-dimensional model is generated using the simulated face. The three-dimensional model is generated from features identified in the simulated face, which may be a two-dimensional image. The 3-D model will generate the face with dimensionality and depth, including proportions for the head of the person that does not exist. In some embodiment, Deep Convolutional Neural Networks (DCNN) and Generative Adversarial Networks (GANs) are utilized to approximate the depth and 3-D shaping of the facial features, shapes, depth and texture, based on the two-dimensional image of the simulated face. In some embodiments, linear statistical models of facial texture and shape are used, e.g., 3-D Morphable Models (3DMMs). Commonly, 3DMMs use a UV map for representing texture, as UV maps help assign -D texture data into 2-D planes with universal per-pixel alignment for all textures.

For more information on 3-D facial reconstruction, reference may be made to an article entitled “GANFIT: Generative Adversarial Network Fitting for High Fidelity 3D Face Reconstruction,” by Baris Gecer, et al., Imperial College London, FaceSoft.io, University of Middlesex, June 2019. The various types of machine learning an artificial intelligence processing can be utilized in order to optimize the generation of the 3-D model, derived from a two-dimensional image. In the embodiments described herein, the input provided is the simulated face, which is of a person that does not exist, and was generated based on the input attributes and variations defined by the user.

In operation 312, access is provided to the 3-D model to a content creation application. The content creation application can then import the 3-D model as a file, which can then be graphically illustrated on a display window of the application. The 3-D model, in one embodiment, includes the mesh, i.e. wireframe associate with the face, head, hair, and other aspects of the simulated face. In addition, the 3-D model file may also include the texture data, in order to provide skinning to the wire mesh. Using tools provided by the content creation application 202, is possible to make adjustments to the vertices by pushing and pulling on different intersections of the mash. As mentioned above, it is also possible to apply blendshapes to the imported 3-D model. In one embodiment, the blendshapes are automatically created for the imported 3-D model of the face. The blendshapes are selected based on the size, shape, and other properties associated with the face being imported, and for application to a rig of a character to be utilized in a video game.

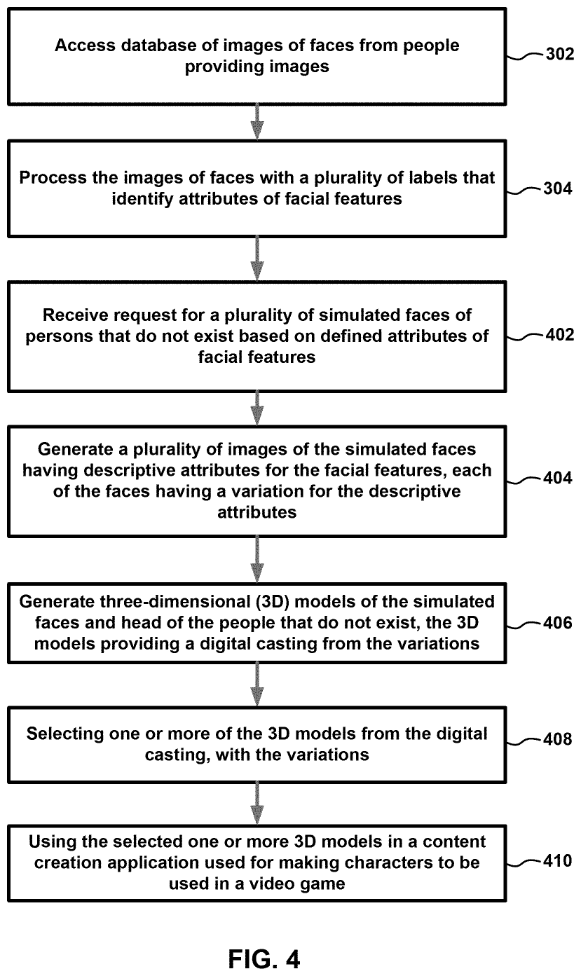

FIG. 4 illustrates another method for generating multiple 3-D models, for use in digital casting of faces, in accordance with one embodiment. In operations 302 and 304, the training process is performed as mentioned above. In operation 402, a request is received for a simulated face of persons that do not exist based on defined attributes of the facial features. In this embodiment, more than one faces being requested, and the variance is defined by the input request. In operation 404, a plurality of images is generated for simulated faces. The simulated faces will have descriptive attributes for the facial features, and each of the faces will have a variation for the descriptive attributes as defined in the request. In operation 406, a 3-D model is generated for each of the simulated faces and head of the people that do not exist.

The 3-D model provides a digital casting for the variations generated. In operation 404, one or more the 3-D models are selected from the digital casting, taking account the variations provided by the settings supplied in the request. In operation 410, the selected one or more 3-D models are used in a content creation application for making characters to be used in a video game.

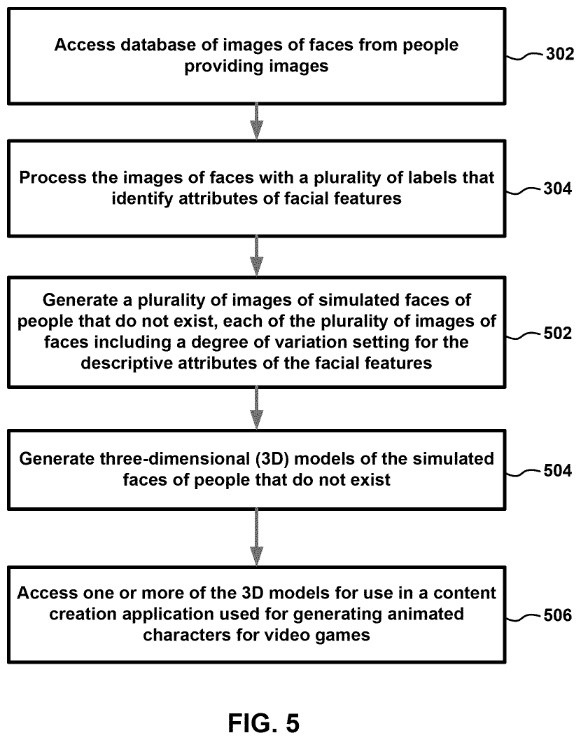

FIG. 5 illustrates another embodiment, where a plurality of 3-D models is generated from a plurality of simulated faces, in accordance with one embodiment. In operations 302 and 304, the training process is performed in order to generate a robust facial rendering model 104, as described above. In operation 502, a plurality of images of simulated faces is generated for people that do not exist. Each of the plurality of images of the faces includes a degree of variation setting for the descriptive attributes of the facial features. In this embodiment, the input provided via the content creation application can be to generate multiple simulated faces having different characteristics or random characteristics.

The objective enabled by this feature is to generate many simulated faces that can then be quickly turned into 3-D models in operation 504, for implementation as characters in a game. In operation 506, access is provided to the generated 3-D models for use in a content creation application for further animation of the characters to be used in video games. By way of example, when many different types of face simulations are requested, is possible to use these simulated faces as non-player characters (NPCs). In one embodiment, NPCs will require less fidelity or resolution, which makes the generation of many different types of simulated faces more efficient for the process, instead of having to generate one face at a time. In contrast, if the face being generated is for a main character or a hero character, then more time would be spent generated higher fidelity 3-D model, and then further processing to make adjustments to the generated 3-D model using the content creation application.

By way of example, NPCs are typically utilizes background characters and scenes where the main character traverses, and players typically are not focused on the faces of these NPCs. For this reason, less time can be spent generating simulated faces for NPCs, while also speeding up the process of generating those faces using variation templates, as described with reference to FIGS. 2B-2D.

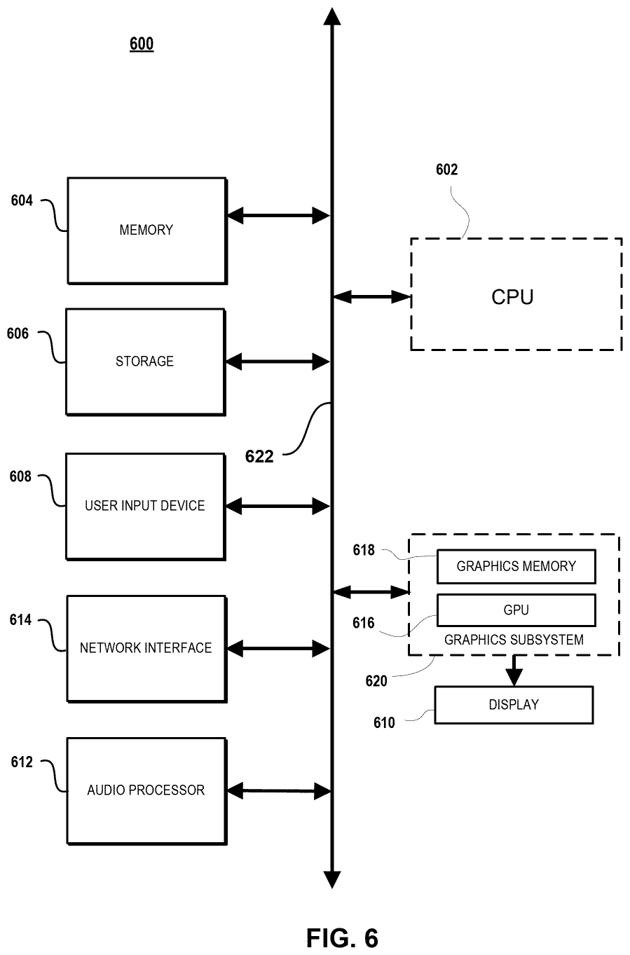

FIG. 6 illustrates components of an example device 600 that can be used to perform aspects of the various embodiments of the present disclosure. This block diagram illustrates a device 600 that can incorporate or can be a personal computer, video game console, personal digital assistant, a server or other digital device, suitable for practicing an embodiment of the disclosure. Device 600 includes a central processing unit (CPU) 602 for running software applications and optionally an operating system. CPU 602 may be comprised of one or more homogeneous or heterogeneous processing cores.

In one embodiment, the video game is executed either locally on a gaming machine, a personal computer, or on a server. In some cases, the video game is executed by one or more servers of a data center. When the video game is executed, some instances of the video game may be a simulation of the video game. For example, the video game may be executed by an environment or server that generates a simulation of the video game. The simulation, on some embodiments, is an instance of the video game. In other embodiments, the simulation maybe produced by an emulator. In either case, if the video game is represented as a simulation, that simulation is capable of being executed to render interactive content (i.e., video frames) that can be interactively streamed, executed, and/or controlled by user input.

The CPU 602 is one or more general-purpose microprocessors having one or more processing cores. Further embodiments can be implemented using one or more CPUs with microprocessor architectures specifically adapted for highly parallel and computationally intensive applications, such as processing operations of interpreting a query, identifying contextually relevant resources, and implementing and rendering the contextually relevant resources in a video game immediately. Device 600 may be a localized to a player playing a game segment (e.g., game console), or remote from the player (e.g., back-end server processor), or one of many servers using virtualization in a game cloud system for remote streaming of gameplay to clients.

Memory 604 stores applications and data for use by the CPU 602. Storage 606 provides non-volatile storage and other computer readable media for applications and data and may include fixed disk drives, removable disk drives, flash memory devices, and CD-ROM, DVD-ROM, Blu-ray, HD-DVD, or other optical storage devices, as well as signal transmission and storage media. User input devices 608 communicate user inputs from one or more users to device 600, examples of which may include keyboards, mice, joysticks, touch pads, touch screens, still or video recorders/cameras, tracking devices for recognizing gestures, and/or microphones.

Network interface 614 allows device 600 to communicate with other computer systems via an electronic communications network, and may include wired or wireless communication over local area networks and wide area networks such as the internet. An audio processor 612 is adapted to generate analog or digital audio output from instructions and/or data provided by the CPU 602, memory 604, and/or storage 606. The components of device 600, including CPU 602, memory 604, data storage 606, user input devices 608, network interface 610, and audio processor 612 are connected via one or more data buses 622.

A graphics subsystem 620 is further connected with data bus 622 and the components of the device 600. The graphics subsystem 620 includes a graphics processing unit (GPU) 616 and graphics memory 618. Graphics memory 618 includes a display memory (e.g., a frame buffer) used for storing pixel data for each pixel of an output image. Graphics memory 618 can be integrated in the same device as GPU 608, connected as a separate device with GPU 616, and/or implemented within memory 604. Pixel data can be provided to graphics memory 618 directly from the CPU 602. Alternatively, CPU 602 provides the GPU 616 with data and/or instructions defining the desired output images, from which the GPU 616 generates the pixel data of one or more output images. The data and/or instructions defining the desired output images can be stored in memory 604 and/or graphics memory 618. In an embodiment, the GPU 616 includes 3-D rendering capabilities for generating pixel data for output images from instructions and data defining the geometry, lighting, shading, texturing, motion, and/or camera parameters for a scene. The GPU 616 can further include one or more programmable execution units capable of executing shader programs.

The graphics subsystem 614 periodically outputs pixel data for an image from graphics memory 618 to be displayed on display device 610. Display device 610 can be any device capable of displaying visual information in response to a signal from the device 600, including CRT, LCD, plasma, and OLED displays. Device 600 can provide the display device 610 with an analog or digital signal, for example.

It should be noted, that access services, such as providing access to games of the current embodiments, delivered over a wide geographical area often use cloud computing. Cloud computing is a style of computing in which dynamically scalable and often virtualized resources are provided as a service over the Internet. Users do not need to be an expert in the technology infrastructure in the “cloud” that supports them. Cloud computing can be divided into different services, such as Infrastructure as a Service (IaaS), Platform as a Service (PaaS), and Software as a Service (SaaS). Cloud computing services often provide common applications, such as video games, online that are accessed from a web browser, while the software and data are stored on the servers in the cloud. The term cloud is used as a metaphor for the Internet, based on how the Internet is depicted in computer network diagrams and is an abstraction for the complex infrastructure it conceals.

A game server may be used to perform the operations of the durational information platform for video game players, in some embodiments. Most video games played over the Internet operate via a connection to the game server. Typically, games use a dedicated server application that collects data from players and distributes it to other players. In other embodiments, the video game may be executed by a distributed game engine. In these embodiments, the distributed game engine may be executed on a plurality of processing entities (PEs) such that each PE executes a functional segment of a given game engine that the video game runs on. Each processing entity is seen by the game engine as simply a compute node.

Game engines typically perform an array of functionally diverse operations to execute a video game application along with additional services that a user experiences. For example, game engines implement game logic, perform game calculations, physics, geometry transformations, rendering, lighting, shading, audio, as well as additional in-game or game-related services. Additional services may include, for example, messaging, social utilities, audio communication, game play replay functions, help function, etc. While game engines may sometimes be executed on an operating system virtualized by a hypervisor of a particular server, in other embodiments, the game engine itself is distributed among a plurality of processing entities, each of which may reside on different server units of a data center.

According to this embodiment, the respective processing entities for performing the may be a server unit, a virtual machine, or a container, depending on the needs of each game engine segment. For example, if a game engine segment is responsible for camera transformations, that particular game engine segment may be provisioned with a virtual machine associated with a graphics processing unit (GPU) since it will be doing a large number of relatively simple mathematical operations (e.g., matrix transformations). Other game engine segments that require fewer but more complex operations may be provisioned with a processing entity associated with one or more higher power central processing units (CPUs).

By distributing the game engine, the game engine is provided with elastic computing properties that are not bound by the capabilities of a physical server unit. Instead, the game engine, when needed, is provisioned with more or fewer compute nodes to meet the demands of the video game. From the perspective of the video game and a video game player, the game engine being distributed across multiple compute nodes is indistinguishable from a non-distributed game engine executed on a single processing entity, because a game engine manager or supervisor distributes the workload and integrates the results seamlessly to provide video game output components for the end user.

Users access the remote services with client devices, which include at least a CPU, a display and I/O. The client device can be a PC, a mobile phone, a netbook, a PDA, etc. In one embodiment, the network executing on the game server recognizes the type of device used by the client and adjusts the communication method employed. In other cases, client devices use a standard communications method, such as html, to access the application on the game server over the internet.

It should be appreciated that a given video game or gaming application may be developed for a specific platform and a specific associated controller device. However, when such a game is made available via a game cloud system as presented herein, the user may be accessing the video game with a different controller device. For example, a game might have been developed for a game console and its associated controller, whereas the user might be accessing a cloud-based version of the game from a personal computer utilizing a keyboard and mouse. In such a scenario, the input parameter configuration can define a mapping from inputs which can be generated by the user's available controller device (in this case, a keyboard and mouse) to inputs which are acceptable for the execution of the video game.

In another example, a user may access the cloud gaming system via a tablet computing device, a touchscreen smartphone, or other touchscreen driven device. In this case, the client device and the controller device are integrated together in the same device, with inputs being provided by way of detected touchscreen inputs/gestures. For such a device, the input parameter configuration may define particular touchscreen inputs corresponding to game inputs for the video game. For example, buttons, a directional pad, or other types of input elements might be displayed or overlaid during running of the video game to indicate locations on the touchscreen that the user can touch to generate a game input. Gestures such as swipes in particular directions or specific touch motions may also be detected as game inputs. In one embodiment, a tutorial can be provided to the user indicating how to provide input via the touchscreen for gameplay, e.g. prior to beginning gameplay of the video game, so as to acclimate the user to the operation of the controls on the touchscreen.

In some embodiments, the client device serves as the connection point for a controller device. That is, the controller device communicates via a wireless or wired connection with the client device to transmit inputs from the controller device to the client device. The client device may in turn process these inputs and then transmit input data to the cloud game server via a network (e.g. accessed via a local networking device such as a router). However, in other embodiments, the controller can itself be a networked device, with the ability to communicate inputs directly via the network to the cloud game server, without being required to communicate such inputs through the client device first. For example, the controller might connect to a local networking device (such as the aforementioned router) to send to and receive data from the cloud game server. Thus, while the client device may still be required to receive video output from the cloud-based video game and render it on a local display, input latency can be reduced by allowing the controller to send inputs directly over the network to the cloud game server, bypassing the client device.

In one embodiment, a networked controller and client device can be configured to send certain types of inputs directly from the controller to the cloud game server, and other types of inputs via the client device. For example, inputs whose detection does not depend on any additional hardware or processing apart from the controller itself can be sent directly from the controller to the cloud game server via the network, bypassing the client device. Such inputs may include button inputs, joystick inputs, embedded motion detection inputs (e.g. accelerometer, magnetometer, gyroscope), etc. However, inputs that utilize additional hardware or require processing by the client device can be sent by the client device to the cloud game server. These might include captured video or audio from the game environment that may be processed by the client device before sending to the cloud game server. Additionally, inputs from motion detection hardware of the controller might be processed by the client device in conjunction with captured video to detect the position and motion of the controller, which would subsequently be communicated by the client device to the cloud game server. It should be appreciated that the controller device in accordance with various embodiments may also receive data (e.g. feedback data) from the client device or directly from the cloud gaming server.

It should be understood that the various embodiments defined herein may be combined or assembled into specific implementations using the various features disclosed herein. Thus, the examples provided are just some possible examples, without limitation to the various implementations that are possible by combining the various elements to define many more implementations. In some examples, some implementations may include fewer elements, without departing from the spirit of the disclosed or equivalent implementations.

Embodiments of the present disclosure may be practiced with various computer system configurations including hand-held devices, microprocessor systems, microprocessor-based or programmable consumer electronics, minicomputers, mainframe computers and the like. Embodiments of the present disclosure can also be practiced in distributed computing environments where tasks are performed by remote processing devices that are linked through a wire-based or wireless network.

Although the method operations were described in a specific order, it should be understood that other housekeeping operations may be performed in between operations, or operations may be adjusted so that they occur at slightly different times or may be distributed in a system which allows the occurrence of the processing operations at various intervals associated with the processing, as long as the processing of the telemetry and game state data for generating modified game states and are performed in the desired way.

One or more embodiments can also be fabricated as computer readable code on a computer readable medium. The computer readable medium is any data storage device that can store data, which can thereafter be read by a computer system. Examples of the computer readable medium include hard drives, network attached storage (NAS), read-only memory, random-access memory, CD-ROMs, CD-Rs, CD-RWs, magnetic tapes and other optical and non-optical data storage devices. The computer readable medium can include computer readable tangible medium distributed over a network-coupled computer system so that the computer readable code is stored and executed in a distributed fashion.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within the scope and equivalents of the appended claims.

What is claimed is:

1. A method for automatically generating a three-dimensional model of a face not based on a real person, comprising,
accessing a database of images of faces;
processing the images through a machine learning process to identify and label features of each of the faces, the labels providing a descriptive characteristic of the faces, the machine learning process produces a facial rendering model;
generating an image of a simulated face based on a request that includes attributes for facial features to be included in the simulated face;
generating a three-dimensional (3-D) model based on the simulated face, the 3-D model is defined in a file that includes wire mesh data for the simulated face and texture data for the simulated face; and
accessing the file via a content creation application, the file enabling use of the 3-D model on a rig of a character to be animated for a video game.

2. The method of claim 1, wherein the attributes for the facial features of the simulated face are associated with inputs provided by the content creation application for setting an amount of attribute variation of one or more of the attributes.

3. The method of claim 1, further providing a control via the content creation application to set a number of simulated faces to generate based on request.

4. The method of claim 3, wherein the control via the content creation application further provides an input for setting a variation among simulated faces, the input qualifies a degree of similarity between the simulated faces generated when the number of simulated faces is two or more simulated faces.

5. The method of claim 1, the facial rendering model is generated during a face image training process, the face image training process includes processing facial feature extractors that identify facial features in each of the faces and facial feature classifiers that provide for labeling of the features.

6. The method of claim 1, wherein generating the simulated face includes accessing the facial rendering model using the attributes for facial features to be included in the simulated face, the facial rendering model is configured to output data that includes parts of the images from the faces of the database assembled to generate said simulated face, the output data includes blending data used to assemble said parts of images when generating the simulated face, the blending data generated by said machine learning process adjusts said texture data to produce said simulated face as a realistic face of a person that does not exist.

7. The method of claim 1, wherein the requested attributes for facial features to be included in the simulated face include a gender, and a plurality of sub-attributes desired for the simulated face, and one or more of the sub-attributes is associated with an attribute variation set via the content creation application.

8. The method of claim 1, wherein the simulated face is one of a plurality of simulated faces requested to be generated; and
applying a variation amount simulated faces setting that defines how similar or dissimilar each one of the simulated faces is with respect to each other.

9. A method, comprising,
accessing a database of images of faces;
processing the images through a machine learning process to identify and label features of each of the faces to train a facial rendering model;
accessing the facial rendering model to request data for rendering a plurality of simulated faces, the request that includes attributes for facial features and attribute variations between each of the plurality of simulated faces;
processing one or more of the plurality of simulated faces, the processing is configured to generate a three-dimensional (3-D) model based for each respective simulated face, each 3-D model includes wire mesh data and texture data usable by a content creation application;
wherein the facial rendering model enables the plurality simulated faces to be rendered based on a blending of facial parts from the images of faces.

10. The method of claim 9, wherein the request includes input data associated with attribute variation for selected attributes, the attribute variation sets a percentage amount of variation away from an input attribute.

11. The method of claim 9, wherein the facial rendering model is generated during a face image training process, the face image training process includes processing facial feature extractors that identify facial features in each of the faces and facial feature classifiers that provide for labeling of the features.

12. The method of claim 9, wherein generating the simulated faces includes accessing the facial rendering model using the attributes for facial features to be included in the simulated face, the facial rendering model is configured to output data that includes parts of the images from the faces of the database assembled to generate said simulated faces, the output data includes said blending of facial parts from the images of faces when generating the simulated faces, the blending is at least in part controlled by said machine learning process to adjust said texture data to produce realistic simulated faces of people that do not exist.

14. The method of claim 9, wherein the attributes for facial features to be included in the simulated face include a gender, and a plurality of sub-attributes desired for the simulated face, and one or more of the sub-attributes is associated with an attribute variation set via the content creation application.

15. The method of claim 9, wherein each of the simulated faces represents a face of a person that does not exist.

16. The method of claim 9, further comprising,
identifying a set of blendshapes for each one of the simulated faces, the blendshapes being identified based on attributes present in the simulated faces.

17. The method of claim 9, wherein the content creation application uses a plug-in to provide functionality for accessing the facial rendering model to generate said simulated faces and producing said 3-D models.

18. The method of claim 9, wherein the content creation application enables application of the 3-D models of the simulated faces to be applied to one or more rigs of characters.

19. The method of claim 18, wherein the one or more rigs of characters are designed for animation using predefined blendshapes, the predefined blendshapes are automatically created for each of the 3-D models of simulated faces.

20. The method of claim 19, wherein the rigs of characters are usable in one or more video games.
